(19) United States
(12) Patent Application Publication
(10) Pub. No.: US 2010/0062245 A1
(43) Pub. Date: Mar. 11, 2010

(54) SUBSTRATE WHICH IS EQUIPPED WITH A STACK HAVING THERMAL PROPERTIES

(75) Inventors: Estelle Martin, Paris (FR); Nicolas Nadaud, Paris (FR); Sylvain Belliot, Paris (FR); Eric Mattmann, Paris (FR); Pascal Reutler, Paris (FR)

Correspondence Address: OBLON, SPIVAK, MCCLELLAND MAIER & NEUSTADT, L.L.P., 1940 DUKE STREET, ALEXANDRIA, VA, 22314, US

(73) Assignee: Saint-Gobain Glass France, Courbevoie (FR)

(21) Appl. No.: 12/092,083

(22) PCT Filed: Nov. 8, 2006
(86) PCT No.: PCT/FR2006/051151

§ 371 Date: Sep. 4, 2008

(30) Foreign Application Priority Data
Nov. 8, 2005 (FR) 0553385

(51) Int. Cl. B32B 5/00; B32B 9/00; B32B 15/04; B32B 17/06; B32B 1/00; C23C 14/34

(52) U.S. Cl. 428/336; 428/688; 428/457; 428/697; 428/698; 428/702; 428/472; 428/472.2; 428/469; 428/432; 428/426; 428/174; 204/192.1

(57) ABSTRACT

The invention relates to a substrate (10), especially a transparent glass substrate, provided with a thin-film multilayer coating comprising an alternation of n functional layers (40) having reflection properties in the infrared and/or in solar radiation, especially metallic functional layers based on silver, and (n+1) dielectric films (20, 60), where n≧1, said films being composed of a layer or a plurality of layers (22, 24, 62, 64), so that each functional layer (40) is placed between at least two dielectric films (20, 60), characterized in that at least one functional layer (40) includes a blocker film (30, 50) consisting of:
on the one hand, an interface layer (32, 52) immediately in contact with said functional layer, this interface layer being made of a material that is not a metal; and
on the other hand, at least one metal layer (34, 54) made of a metallic material, immediately in contact with said interface layer (32, 52).

The invention relates to transparent substrates, especially those made of a rigid mineral material such as glass, said substrates being coated with a thin-film multilayer coating comprising at least one functional layer of metallic type which can act on solar radiation and/or infrared radiation of long wavelength.

The invention relates more particularly to the use of such substrates for manufacturing thermal insulation and/or solar protection glazing units. These glazing units are intended for equipping both buildings and vehicles, especially with a view to reducing air-conditioning load and/or reducing excessive overheating (glazing called “solar control” glazing) and/or reducing the amount of energy dissipated to the outside (glazing called “low-E” or “low-emissivity” glazing) brought about by the ever growing use of glazed surfaces in buildings and vehicle passenger compartments.

One type of multilayer coating known for giving substrates such properties consists of at least one metallic functional layer, such as a silver layer, which is placed between two films made of dielectric material of the metal oxide or nitride type. This multilayer coating is generally obtained by a succession of deposition operations carried out using a vacuum technique, such as sputtering, possibly magnetically enhanced or magnetron sputtering. Two very thin films may also be provided, these being placed on each side of the silver layer—the subjacent film as a tie, nucleation and/or protection layer, for protection during a possible heat treatment subsequent to the deposition, and the superjacent film as a “sacrificial” or protection layer so as to prevent the silver from being impaired if the oxide layer that surmounts it is deposited by sputtering in the presence of oxygen and/or if the multilayer coating undergoes a heat treatment subsequent to the deposition.

Thus, multilayer coatings of this type, with one or two silver-based metallic functional layers, are known from European patents EP-0 611 213, EP-0 678 484 and EP-0 638 528.

Currently, there is an increasing demand for this low-emissivity or solar-protection glazing to also have characteristics inherent in the substrates themselves, especially esthetic characteristics (for the glazing to be able to be curved), mechanical properties (to be stronger) or safety characteristics (to cause no injury by broken fragments). This requires the glass substrates to undergo heat treatments known per se, of the bending, annealing or toughening type, and/or treatments associated with the production of laminated glazing.

The multilayer coating then has to be adapted in order to preserve the integrity of the functional layers of the silver-layer type, especially to prevent their impairment. A first solution consists in significantly increasing the thickness of the abovementioned thin metal layers that surround the functional layers: thus, measures are taken to ensure that any oxygen liable to diffuse from the ambient atmosphere and/or to migrate from the glass substrate at high temperature is “captured” by these metal layers, which oxidizes them, without it reaching the functional layer(s).

These layers are sometimes called “blocking layers” or “blocker layers”.

One may especially refer to patent application EP-A-0 506 507 for the description of a “toughenable” multilayer coating having a silver layer placed between a tin layer and a nickel-chromium layer. However, it is clear that the substrate coated before the heat treatment was considered merely as a “semifinished” product—the optical characteristics frequently rendered it unusable as it was. It was therefore necessary to develop and manufacture, in parallel, two types of multilayer coating, one for noncurved/nontoughened glazing and the other for glazing intended to be toughened or curved, which may be complicated, especially in terms of stock management and production.

An improvement proposed in patent EP-0 718 250 has allowed this constraint to be overcome, the teaching of that document consisting in devising a thin-film multilayer coating such that its optical and thermal properties remain virtually unchanged, whether or not the substrate once coated with the multilayer coating undergoes a heat treatment. Such a result is achieved by combining two characteristics:
on the one hand, a layer made of a material capable of acting as a barrier to high-temperature oxygen diffusion is provided on top of the functional layer(s), which material itself does not undergo, at high temperature, a chemical or structural change that would modify its optical properties. Thus, the material may be silicon nitride Si₃N₄ or aluminum nitride AlN; and
on the other hand, the functional layer(s) is (are) directly in contact with the subjacent dielectric, especially zinc oxide ZnO, coating.

A single blocker layer (or monolayer blocker coating) is also, preferably, provided on the functional layer or layers. This blocker layer is based on a metal chosen from niobium Nb, tantalum Ta, titanium Ti, chromium Cr or nickel Ni or from an alloy based on at least two of these metals, especially a niobium/tantalum (Nb/Ta) alloy, a niobium/chromium (Nb/Cr) alloy or a tantalum/chromium (Ta/Cr) alloy or a nickel/chromium (Ni/Cr) alloy.

Although this solution does actually allow the substrate after heat treatment to preserve a T_{L} level and an appearance in external reflection that are quite constant, it is still capable of improvement.

Moreover, the search for a better resistivity of the multilayer coating, that is to say a lower resistivity, is a constant search.

The state of the functional layer has been the subject of many studies as it is, of course, a major factor in the resistivity of the functional layer.

The inventors have chosen to explore another approach for improving the resistivity, namely the nature of the interface between the functional layer and the immediately adjacent blocker layer.

The prior art teaches, from international patent application WO 2004/058660, a solution whereby the overblocker film is an NICrOₓ monolayer, possibly having an oxidation gradient. According to that document, the part of the blocker layer in contact with the functional layer is less oxidized than the part of this layer further away from the functional layer using a particular deposition atmosphere.

The object of the invention is therefore to remedy the drawbacks of the prior art, by developing a novel type of multilayer coating comprising one or more functional layers of the type of those described above, which multilayer coating can undergo high-temperature heat treatments of the bending, toughening or annealing type while preserving its optical quality and its mechanical integrity and having an improved resistivity.

The invention constitutes in particular a suitable solution to the usual problems of the intended application and consists in developing a compromise between the thermal properties and the optical qualities of the thin-film multilayer coating.

In fact, improving the resistivity, the reflection properties in the infrared and the emissivity of a multilayer coating usually causes a deterioration in the light transmission and thin colours reflection of this multilayer coating.

Thus, the subject of the invention, in its broadest acceptance, is a substrate, especially a transparent glass substrate, provided with a thin-film multilayer coating comprising an alternation of n functional layers having reflection properties in the infrared and/or in solar radiation, especially metallic functional layers based on silver or on a metal alloy containing silver, and (n+1) dielectric films, where n≧1, (n of course being an integer), said dielectric films being composed of a layer or a plurality of layers, including at least one made of a dielectric material, so that each functional layer is placed between at least two dielectric films, characterized in that at least one functional layer includes a blocker film consisting of:
on the one hand, an interface layer immediately in contact with said functional layer, this interface layer being made of a material that is not a metal; and
on the other hand, at least one metal layer made of a metallic material, immediately in contact with said interface layer.

The invention thus consists in providing an at least bilayer blocker film for the functional layer, this blocker film being located beneath the functional layer (“underblocker” film) and/or on the functional layer (“overblocker” film).

The inventors have thus taken into consideration the fact that the state of oxidation, and even the degree of oxidation, of the layer immediately in contact with the functional layer could have a major influence on the resistivity of the layer.

The invention does not only apply to multilayer coatings comprising a single “functional” layer placed between two films. It also applies to multilayer coatings having a plurality of functional layers, especially two functional layers alternating with three films, or three functional layers alternating with four films, or even four functional layers alternating with five films.

In the case of a multilayer coating having multiple functional layers, at least one functional layer, and preferably each functional layer, is provided with an underblocker film and/or with an overblocker film according to the invention, that is to say a blocker film comprising at least two separate layers, these separate layers being deposited using different separate targets.

The interface layer, in contact with the functional layer, is preferably based on an oxide and/or on a nitride, and more preferably is an oxide, a nitride or an oxynitride of a metal chosen from at least one of the following metals: Ti, V, Mn, Fe, Co, Cu, Zn, Zr, Hf, Al, Nb, Ni, Cr, Mo, Ta, W, or from an oxide of an alloy based on at least one of these materials. This interface layer is deposited in nonmetallic form.

The metallic layer of the blocker film, in contact with the interface layer, preferably consists of a material chosen from at least one of the following metals: Ti, V, Mn, Co, Cu, Zn, Zr, Hf, Al, Nb, Ni, Cr, Mo, Ta, or of an alloy based on at least one of these materials.

In one particular embodiment, this metallic layer is based on titanium.

The metallic layer of the blocker film, which is deposited in metallic form, is, of course, not a metallic functional layer having reflection properties in the infrared and/or in solar radiation.

In another particular embodiment, the interface layer is an oxide, a nitride or an oxynitride of a metal (or metals) that is (or are) present in the adjacent metallic layer.

In another particular embodiment, the interface layer is partially oxidized. It is therefore not deposited in stoichiometric form but in substoichiometric form, of the MOₓ type, where M represents the material and x is a number below the stoichiometry of the oxide of the material. Preferably, x is between 0.75 times and 0.99 times the normal stoichiometry of the oxide.

In one particular embodiment, the interface layer is based on TiOₓ and x may in particular be such that 1.5≦x≦1.98 or 1.5<x<1.7 or even 1.7≦x≦1.95.

In another particular embodiment, the interface layer is partially nitrided. It is therefore not deposited in stoichiometric form but in substoichiometric form, of the MN_{y} type, where M represents the material and y is a number below the stoichiometry of the nitride of the material. Preferably, y is between 0.75 times and 0.99 times the normal stoichiometry of the nitride.

Likewise, the interface layer may also be partially oxynitrided.

The interface layer preferably has a geometric thickness of less than 5 nm and preferably between 0.5 and 2 nm, and the metallic layer preferably has a geometric thickness of less than 5 nm and preferably between 0.5 and 2 nm.

The blocker film preferably has a geometric thickness of less than 10 nm and preferably between 1 and 4 nm.

The functionality of a metallic overblocker layer, for example made of Ti, is to protect the subjacent metallic functional layer during deposition of the next layer, that is to say the layer deposited just after the overblocker film, in particular when this layer is an oxide, such as for example a layer based on ZnO.

It has been found that a metallic protective layer, sometimes called a sacrificial layer, as a single layer of a blocker film and in particular an overblocker film, for example made of Ti, greatly improves the electron conduction properties of the functional layer. Thus it has been observed that, before and after the heat treatment, there is a slight overall reduction in the resistivity when the thickness of the metallic titanium layer between the functional layer and this oxide increases, up to an optimal thickness.

However, going beyond the optimum thickness results in an increase in the resistivity, both before and after the heat treatment.

For specimens before the heat treatment, this behavior is unexpected since the increase in thickness of the deposited metal favors, in a simple model, electron transport. Thus, a more complex mechanism must be considered, which actually is unknown at the moment.

It is possible to prove that the reflectivity of electrons at the interface between the functional layer and the blocker film influences this unexpected increase in resistivity for large blocker film thicknesses.

The effect underlying the invention may be confirmed by local chemical analysis carried out in contact with the functional layer and with the blocker film using transmission electron microscopy (TEM) combined with electron energy loss spectroscopy (EELS). This analysis has proved experimentally that an oxygen gradient is formed over the thickness of the blocker film.

The glazing according to the invention incorporates at least the substrate carrying the multilayer coating according to the invention, optionally combined with at least one other substrate. Each substrate may be clear or tinted. At least one of the substrates may especially be made of bulk-tinted glass. The choice of coloration type will depend on the level of light transmission and/or on the colorimetric appearance that is/are desired for the glazing once its manufacture has been completed.

Thus, for glazing intended to equip vehicles, standards impose that windshields have a light transmission T_{L} of about 75% according to some standards or 70% according to other standards, such a level of transmission not being required for the side windows or a sunroof for example. The tinted glass that can be used is for example that, for a thickness of 4 mm, having a T_{L} of 65% to 95%, an energy transmission TE of 40% to 80%, a dominant wavelength in transmission of 470 nm to 525 nm, associated with a transmission purity of 0.4% to 6% under illuminant D₆₅, which may “result”, in the (L,a*,b*) colorimetry system, in a* and b* values in transmission of between −9 and 0 and between −8 and +2, respectively.

For glazing intended to equip buildings, it preferably has a light transmission T_{L} of at least 75% or higher in the case of “low-E” applications, and a light transmission T_{L} of at least 40% or higher for “solar control” applications.

The glazing according to the invention may have a laminated structure, especially one combining at least two rigid substrates of the glass type with at least one sheet of thermoplastic polymer, so as to have a structure of the type: glass/thin-film multilayer coating/sheet(s)/glass. The polymer may especially be based on polyvinyl butyral (PVB), ethylene/vinyl acetate (EVA), polyethylene terephthalate (PET) or polyvinyl chloride (PVC).

The glazing may also have what is called an asymmetric laminated glazing structure, which combines a rigid substrate of the glass type with at least one sheet of polymer of the polyurethane type having energy-absorbing properties, optionally combined with another layer of polymers having “self-healing” properties. For further details about this type of glazing, the reader may refer especially to patents EP-0 132 198, EP-0 131 523 and EP-0 389 354. The glazing may therefore have a structure of the type: glass/thin-film multilayer coating/polymer sheet(s).

In a laminated structure, the substrate carrying the multilayer coating is preferably in contact with a sheet of polymer.

The glazing according to the invention is capable of undergoing a heat treatment without damaging the thin-film multilayer coating. The glazing is therefore possibly curved and/or toughened.

The glazing may be curved and/or toughened when consisting of a single substrate, that provided with the multilayer coating. Such glazing is then referred to as “monolithic” glazing. When it is curved, especially for the purpose of making windows for vehicles, the thin-film multilayer coating preferably is on an at least partly nonplanar face.

The glazing may also be a multiple glazing unit, especially a double-glazing unit, at least the substrate carrying the multilayer coating being curved and/or toughened. It is preferable in a multiple glazing configuration for the multilayer coating to be placed so as to face the intermediate gas-filled space.

When the glazing is monolithic or is in the form of multiple glazing of the double-glazing or laminated glazing type, at least the substrate carrying the multilayer coating may be made of curved or toughened glass, it being possible for the substrate to be curved or toughened before or after the multilayer coating has been deposited.

The invention also relates to a process for manufacturing substrates according to the invention, which consists in depositing the thin-film multilayer coating on its substrate, in particular made of glass, by a vacuum technique of the sputtering, optionally magnetron sputtering, type.

It is then possible to carry out a bending, toughening or annealing heat treatment on the coated substrate without degrading its optical and/or mechanical quality.

However, it is not excluded for the first layer or first layers to be able to be deposited by another technique, for example by a thermal decomposition technique of the pyrolysis or CVD type.

In the process according to the invention, each layer of the blocker film is deposited by sputtering from a target having a different composition from the target used for depositing the layer adjacent to at least the blocker film.

However, it is possible that the targets used for depositing the layers of the blocker film are based on the same chemical element, in particular based on Ti.

The interface layer is preferably deposited using a ceramic target in a nonoxidizing atmosphere (i.e. without intentional introduction of oxygen) preferably consisting of a noble gas (He, Ne, Xe, Ar, or Kr).

Preferably, the metallic layer is deposited using a metal target in an inert atmosphere (i.e. without intentional introduction of oxygen or nitrogen) consisting of a noble gas (He, Ne, Xe, Ar or Kr).

The details and advantageous features of the invention will emerge from the following nonlimiting examples illustrated by means of the figures thereto:

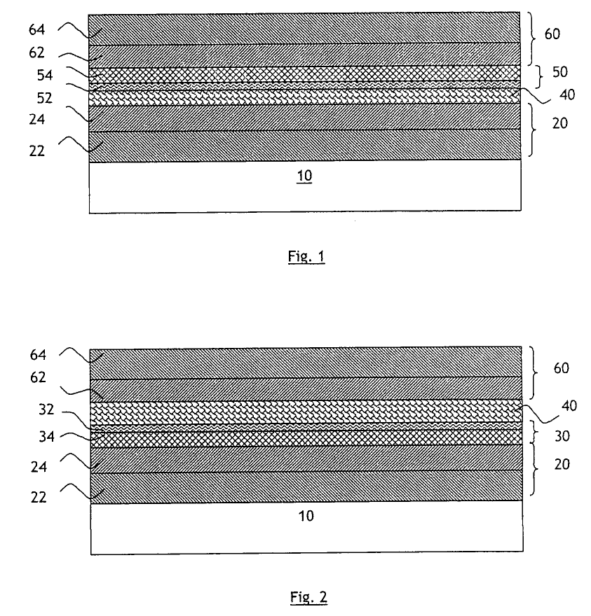

FIG. 1 illustrates a multilayer coating that includes a single functional layer, the functional layer of which is coated with a blocker film according to the invention;

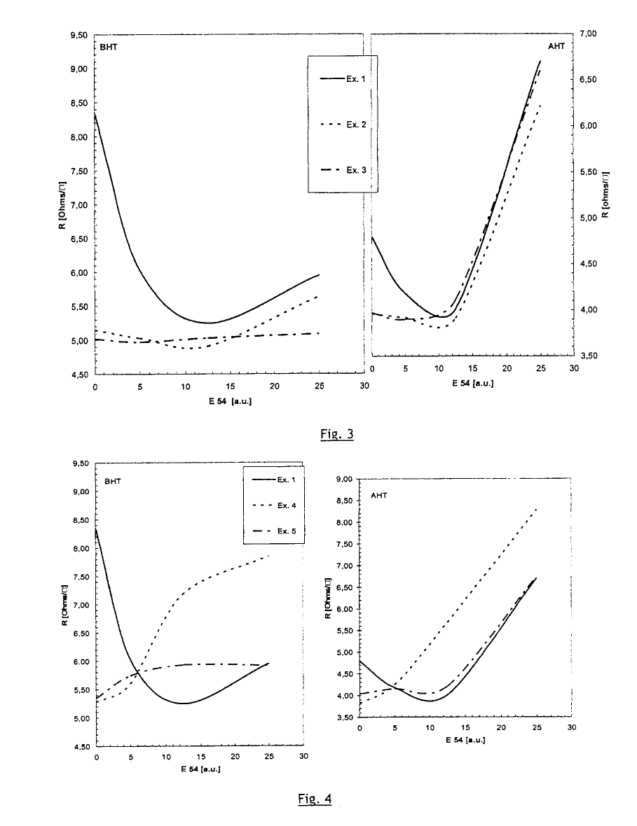

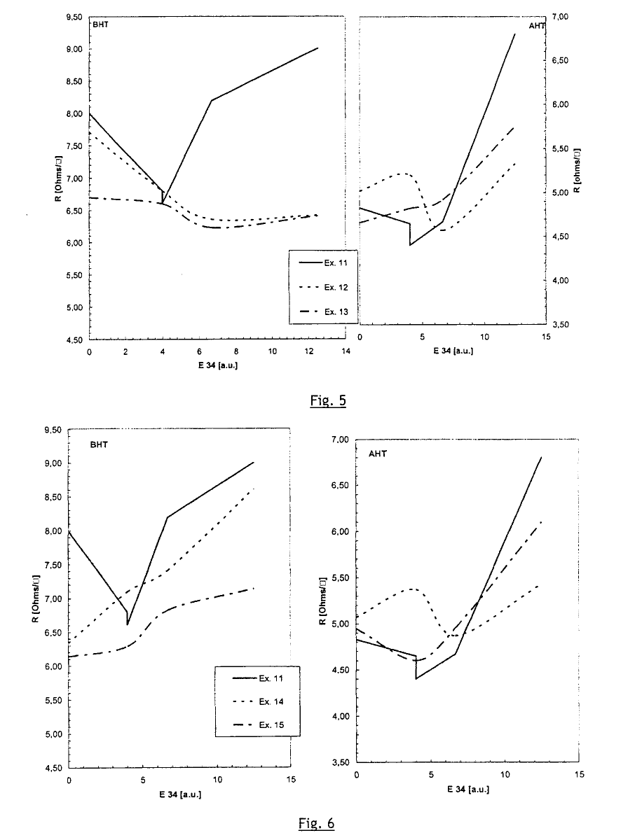

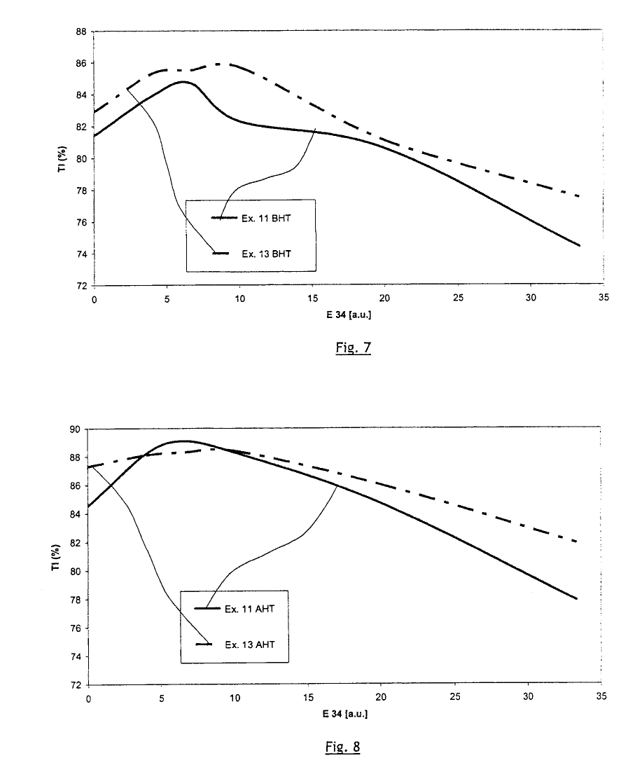

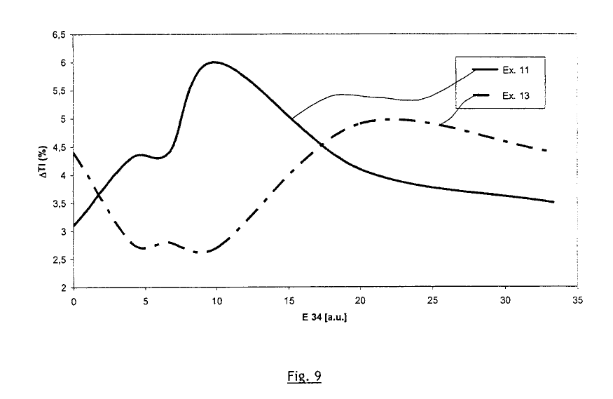

FIG. 2 illustrates a multilayer coating that includes a single functional layer, the functional layer of which is deposited on a blocker film according to the invention;

FIG. 3 illustrates the resistivity of three examples, example 1 not according to the invention and examples 2 and 3 according to the invention, as a function of the thickness of the metal layer in the overblocker film of the multilayer coating of FIG. 1;

FIG. 4 illustrates the resistivity of three examples, example 1 not according to the invention and examples 4 and 5 according to the invention, as a function of the thickness of the metal layer in the overblocker film of the multilayer coating of FIG. 1;

FIG. 5 illustrates the resistivity of three examples, example 11 not according to the invention and examples 12 and 13 according to the invention, as a function of the thickness of the metal layer in the underblocker film of the multilayer coating of FIG. 2;

FIG. 6 illustrates the resistivity of three examples, example 11 not according to the invention and examples 14 and 15 according to the invention, as a function of the thickness of the metal layer in the underblocker film of the multilayer coating of FIG. 3;

FIG. 7 illustrates the light transmission before heat treatment of two examples, example 11 not according to the invention and example 13 according to the invention, as a function of the thickness of the metal layer in the underblocker film of the multilayer coating of FIG. 2;

FIG. 8 illustrates the light transmission after heat treatment of two examples, example 11 not according to the invention and example 13 according to the invention, as a function of the thickness of the metal layer in the underblocker film of the multilayer coating of FIG. 2;

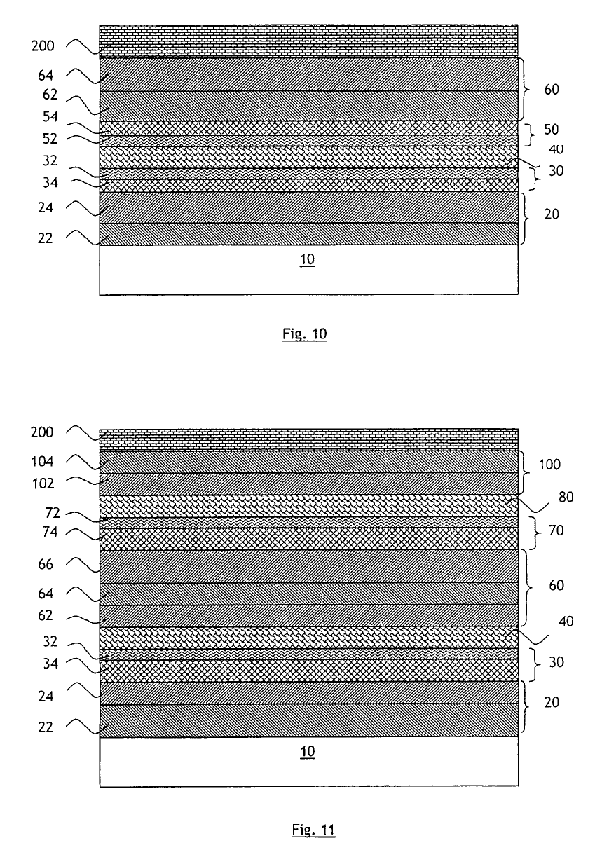

FIG. 9 illustrates the change in light transmission between measurements carried out before the heat treatment and measurements carried out after the heat treatment for the two examples 11 and 13 as a function of the thickness of the metal layer in the underblocker film;

FIG. 10 illustrates a multilayer coating that includes a single functional layer, the functional layer being deposited on an overblocker film according to the invention and beneath an underblocker film according to the invention;

FIG. 11 illustrates a multilayer coating that includes two functional layers, each functional layer being deposited on an underblocker film according to the invention; and

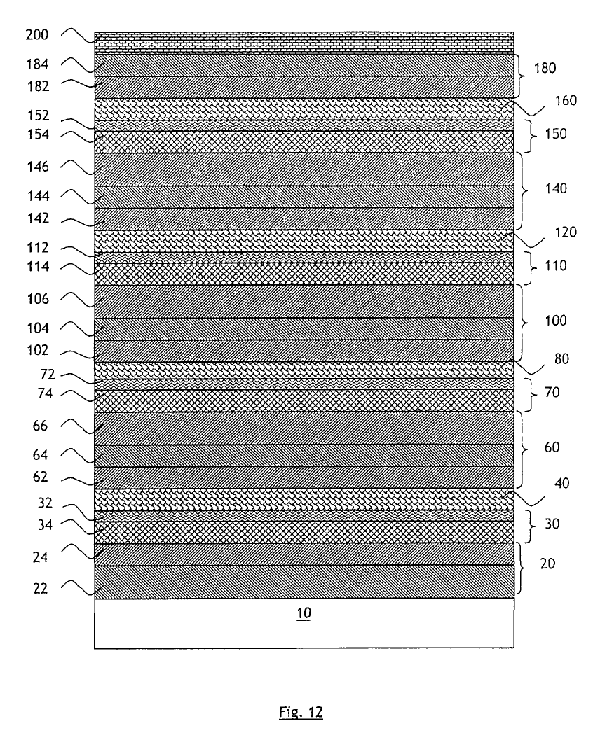

FIG. 12 illustrates a multilayer coating that includes four functional layers, each functional layer being deposited on an underblocker film according to the invention.

The thicknesses of the various layers of the multilayer coatings in the figures have not been drawn in proportion so as to make them easier to read.

FIGS. 1 and 2 illustrate diagrams of multilayer coatings that include a single functional layer, when the functional layer is provided with an overblocker film and when the functional layer is provided with an underblocker film, respectively.

FIGS. 3 to 6 respectively illustrate the resistivity of the multilayer coatings:
in the case of FIG. 3, examples 1 to 3 produced according to FIG. 1;
in the case of FIG. 4, examples 1, 4 and 5 produced according to FIG. 1;
in the case of FIG. 5, examples 11 to 13 produced according to FIG. 2; and
in the case of FIG. 6, examples 11, 14 and 15 produced according to FIG. 2.

In the examples 1 to 15 that follow, the multilayer coating is deposited on the substrate 10, which is a substrate made of clear soda-lime-silica glass 2.1 mm in thickness. The multilayer coating includes a single silver-based functional layer 40.

Beneath the functional layer 40 is a dielectric film 20 consisting of a plurality of superposed dielectric-based layers 22, 24 and on the functional layer 40 is a dielectric film 60 consisting of a plurality of superposed dielectric-based layers 62, 64.

In examples 1 to 15:
the layers 22 are based on Si₃N₄ and have a physical thickness of 20 nm;
the layers 24 are based on ZnO and have a physical thickness of 8 nm;
the layers 62 are based on ZnO and have a physical thickness of 8 nm;
the layers 64 are based on Si₃N₄ and have a physical thickness of 20 nm; and
the layers 40 are based on silver and have a physical thickness of 10 nm.

In the various examples 1 to 15, only the nature and the thickness of the blocker film change.

In the case of examples 1 and 11, which are counter-examples, the respective blocker film 50, 30 comprises a single metal layer, 54, 34 respectively, here made of titanium metal neither oxidized nor nitrided, this layer being deposited in a pure argon atmosphere. There is therefore no respective interface layer 52, 32.

In the case of examples 2 and 12, which are examples according to the invention, the respective blocker film 50, 30 comprises a respective metal layer 54, 34, here titanium deposited in a pure argon atmosphere, and a respective oxide interface layer 52, 32, here a titanium oxide layer with a thickness of 1 nm, deposited in a pure argon atmosphere using a ceramic cathode.

In the case of examples 3 and 13, which are examples according to the invention, the respective blocker film 50, 30 comprises a respective metal layer 54, 34, here titanium deposited in a pure argon atmosphere, and a respective oxide interface layer 52, 32, here a titanium oxide layer, with a thickness of 2 nm, deposited in a pure argon atmosphere using a ceramic cathode.

In the case of examples 4 and 14, which are examples according to the invention, the respective blocker film 50, 30 comprises a respective metal layer 54, 34, here titanium deposited in a pure argon atmosphere, and a respective oxide interface layer 52, 32, here zinc oxide, with a thickness of 1 nm, deposited in a pure argon atmosphere using a ceramic cathode.

In the case of examples 5 and 15, which are examples according to the invention, the respective blocker film 50, 30 comprises a respective metal layer 54, 34, here titanium deposited in a pure argon atmosphere, and a respective oxide interface layer 52, 32, here zinc oxide, with a thickness of 2 nm, deposited in a pure argon atmosphere using a ceramic cathode.

In all these examples, the successive layers of the multilayer coating are deposited by magnetron sputtering, but any other deposition technique may be envisioned provided that the layers are deposited in a well-controlled manner with well-controlled thicknesses.

The deposition installation comprises at least one sputtering chamber provided with cathodes equipped with targets made of suitable materials, beneath which the substrate 1 passes in succession. These deposition conditions for each of the layers are the following:
the silver-based layers 40 are deposited using a silver target, under a pressure of 0.8 Pa in a pure argon atmosphere;
the ZnO-based layers 24 and 62 are deposited by reactive sputtering using a zinc target, under a pressure of 0.3 Pa and in an argon/oxygen atmosphere; and
the Si₃N₄-based layers 22 and 64 are deposited by reactive sputtering using an aluminum-doped silicon target, under a pressure of 0.8 Pa in an argon/nitrogen atmosphere.

The power densities and the run speeds of the substrate 10 are adjusted in a known manner in order to obtain the desired layer thicknesses.

For each of the examples, various thicknesses of the metal layers 54, 34 were deposited and then the resistance of each multilayer coating was measured, before a heat treatment (BHT) and after this heat treatment (AHT).

The heat treatment applied consists at each time in heating at 620° C. for 5 minutes followed by rapid cooling in the ambient air (at about 25° C.)

The results of the resistance measurements were converted into resistivities R in ohms per square and have been illustrated in the case of resistivity measurements before the heat treatment in the left-hand part of FIGS. 3 and 4 and in the case of the resistivity measurements after heat treatment in the right-hand part of FIGS. 3 and 4.

Thickness E54 and E34 of the metal layers 54 and 34 respectively is expressed in arbitrary units (a.u.) corresponding to 1000 divided by the speed of the substrate through the deposition chamber in cm/min. The precise calibration of the deposited thickness was not performed, but the thicknesses corresponding to 25 a.u. are in any case around 2 nanometers with regard to the parameters used.

Overblocker Film 50

In the case of the additional TiOₓ interface layer, in the left-hand part of FIG. 3, comparison between the resistivity values before heat treatment of example 1 and the resistivity values before heat treatment of examples 2 and 3 clearly shows an improvement in the resistivity of examples 2 and 3, with resistivity values well below those of example 1.

The presence of the additional TiOₓ layer deposited on the silver-based metallic functional layer and beneath the titanium metal layer therefore improves the resistivity before or without heat treatment.

With a TiOₓ thickness of 2 nm (ex. 3), the resistivity obtained is practically constant and very low; with a TiOₓ thickness of 1 nm (ex. 2), the resistivity obtained is also low, although less constant.

In the right-hand part of FIG. 3, comparison between the resistivity values after heat treatment of example 1 and the resistivity values after heat treatment of examples 2 and 3 also clearly shows an improvement in the resistivity in the case of examples 2 and 3, with resistivity values well below those obtained with example 1 for small thicknesses (less than 12.5 a.u.) of titanium metal. For greater titanium metal thicknesses (greater than 12.5 a.u.), corresponding to a residual presence of unoxidized titanium in the interface layer, an increase in resistivity similar to the single titanium metal layer configuration (ex. 1) is observed.

In the case of the additional ZnOₓ interface layer, in the left-hand part of FIG. 4, comparison between the resistivity values before heat treatment of example 1 and the resistivity values before heat treatment of examples 4 and 5 clearly shows an improvement in the resistivity of examples 4 and 5, with resistivity values well below those of example 1 in the case of small thicknesses (less than 7 a.u.) of titanium metal.

The presence of the additional ZnOₓ layer deposited on the silver-based metallic functional layer and beneath the titanium metal layer therefore improves the resistivity before or without heat treatment for these small thicknesses.

With a ZnOₓ thickness of 2 nm (ex. 5), the resistivity obtained is practically constant and low; with a TiOₓ thickness of 1 nm (ex. 4), the resistivity obtained is less constant.

In the right-hand part of FIG. 4, comparison between the resistivity values after heat treatment of example 1 and the resistivity values after heat treatment of examples 4 and 5 also clearly shows an improvement in the resistivity in the case of examples 4 and 5, with resistivity values well below those obtained in example 1 for small thicknesses (less than 5 a.u.) of titanium metal.

In the case of larger titanium metal thicknesses (greater than 5 a.u.), an increase in the resistivity similar to the single titanium metal layer configuration (ex. 1) is observed.

These results prove the strong influence of the state of oxidation at the interface with the silver-based functional metallic layer.

Thus, in the case of the overblocker film, an oxidized state at this interface with the silver-based layer improves the resistivity, whereas a metallic state is to the detriment of the resistivity.

To ensure that this is so, we then carried out the deposition in the same manner as that of examples 3 and 5, except that the atmosphere for depositing the interface layer 52 made of TiOₓ and ZnOₓ was modified: from a nonoxidizing atmosphere, we went to a slightly oxidizing atmosphere with an oxygen flux of 1 sccm for an argon flux of 150 sccm.

We observed that, with only a very slightly oxidizing state, the resistivity of the multilayer coating for small titanium metal thicknesses (less than 12.5 a.u.) of the interface layer was still much higher than in the case of example 1.

Surprisingly, by depositing a titanium metal layer on this layer, if oxidized at the interface with the functional layer, it is possible to recover the usual resistivity values. The fundamental mechanism for this reduction in resistivity at the interface with the oxidized silver is not completely understood. Possibly there is a chemical reaction between the oxide and the titanium metal and/or diffusion of oxygen.

Using electron energy loss spectroscopy (EELS), a profile through the blocker film was obtained in order to determine at which depth the oxygen signal is detectable, that is to say at which depth the blocker is oxidized. This experiment showed that near the functional layer a signal is detected and that the oxygen signal is no longer detected beyond one half the thickness of the blocker film upon going away from the functional layer.

Underblocker Film 30

The case of the underblocker film is more complex than that of the overblocker, since this film influences the heteroepitaxy of the silver on the subjacent oxide layer, in this case based on zinc oxide.

Unlike the overblocker film, the underblocker film is not in general exposed to an oxygen-containing plasma atmosphere. This means that when the underblocker film is made of unoxidized and/or non-nitrided titanium metal, it will of course be neither oxidized nor nitrided at the interface with the silver-based functional layer.

Deposition of an additional oxide interface layer between the metallic blocker layer and the metallic functional layer is thus the only way of controlling the oxygen content at the interface between the underblocker film and the functional metallic layer.

In the case of the additional TiOₓ interface layer, in the left-hand part of FIG. 5, comparison between the resistivity values before heat treatment of example 11 and the resistivity values before heat treatment of examples 12 and 13 clearly shows an improvement in the resistivity of examples 12 and 13 in the case of the larger titanium metal thicknesses (greater than 4 a.u.), with resistivity values well below those of example 11.

The presence of the additional TiOₓ layer deposited on the titanium metal layer and beneath the silver-based metallic functional layer therefore improves the resistivity before or without heat treatment.

With a TiOₓ thickness of 2 nm (ex. 13), the resistivity obtained is practically constant and very low; with a TiOₓ thickness of 1 nm (ex. 12), the resistivity obtained is also low, although less constant.

In the right-hand part of FIG. 5, comparison between the resistivity values after heat treatment of example 11 and the resistivity values after heat treatment of examples 12 and 13 also shows an improvement in the resistivity in the case of examples 12 and 13, with resistivity values well below those obtained with example 11 for larger titanium metal thicknesses (greater than 6 a.u.).

In the case of small titanium metal thicknesses (less than 6 a.u.), a resistivity similar to the single titanium metal layer configuration (ex. 11) is observed.

In the case of the additional ZnOₓ interface layer, in the left-hand part of FIG. 6, comparison between the resistivity values before heat treatment of example 11 and the resistivity values before heat treatment of examples 14 and 15 clearly shows an improvement in the resistivity of examples 14 and 15 for the larger titanium metal thicknesses (greater than 5 a.u.), with resistivity values below those of example 11.

The presence of the additional ZnOₓ layer deposited on the titanium metal layer and beneath the silver-based metallic functional layer therefore improves the resistivity before or without heat treatment.

With a ZnOₓ thickness of 2 nm (Ex. 15), the resistivity obtained is practically constant and low; with a ZnOₓ thickness of 1 nm (Ex. 14), the resistivity obtained is also low, although less constant.

In the right-hand part of FIG. 6, comparison between the resistivity values after heat treatment of example 11 and the resistivity values after heat treatment of examples 14 and 15 also shows an improvement in the resistivity in the case of examples 14 and 15, with resistivity values below those obtained with example 11 in the case of the larger titanium metal thicknesses (greater than 8 a.u.).

For small titanium metal thicknesses (less than 8 a.u.), a resistivity quite similar to the single titanium metal layer configuration (Ex. 11) is observed.

These results also prove the strong influence of the state of oxidation at the interface with the silver-based functional metallic layer.

Thus, in the case of the underblocker film too, an oxidized state at this interface with the silver-based layer improves the resistivity, whereas a metallic state is to the detriment of the resistivity.

As may be seen moreover in FIGS. 7 and 8, the presence of the TiOₓ interface layer 32 improves the light transmission, both before heat treatment (FIG. 7) and after this treatment (FIG. 8), irrespective of the thickness of the subjacent titanium metal layer 34, except over a small titanium metal thickness range, after heat treatment.

Furthermore, for small thicknesses of the titanium metal layer 34 (greater than 0 but less than 18 a.u.), the difference in light transmission before and after heat treatment is small, as may be seen in FIG. 9. This means that, on a glazed surface consisting of glazing panes incorporating substrates according to the invention having layers 34 in this thickness range, only certain substrates of which have undergone a heat treatment, it will be very difficult to distinguish those panes that have undergone a heat treatment from those that have not, by observing the light transmission through all the panes.

Finally, the colorimetry measurements in reflection on the multilayer coating side have shown that, in the case of example 13, the a* and b* values in the Lab system remained within the preferred “color palette”, that is to say with a* values between 0 and 5 and b* values between −3.5 and −9, whereas in the case of example 11, the a* values were between 0 and 9 and the b* values were between −2 and −7, for the same ranges of thickness of the titanium metal layer 34.

The results of the mechanical resistance to the various tests usually carried out on thin-film multilayer coatings (Taber test, Erichsen brush test, etc.) are not very good, but these results are improved by the presence of a protective layer.

Underblocker Film 30 and Overblocker Film 50

FIG. 10 illustrates an embodiment of the invention corresponding to a multilayer coating that includes a single functional layer 40, the functional layer 40 of which is provided with an underblocker film 30 and with an overblocker film 50.

It has been found that the effects obtained for the multilayer coatings of examples 2, 3 and 12, 13 on the one hand and 5, 6 and 15, 16 on the other were accumulative and that the resistivity of the multilayer coating was further improved.

To improve the mechanical resistance, the multilayer coating is covered with a protective layer 200 based on a mixed oxide, such as a mixed tin zinc oxide.

Examples comprising several functional layers were also produced. They result in the same conclusions as previously.

FIG. 11 thus illustrates an embodiment having two silver-based functional metallic layers 40, 80 and three dielectric films 20, 60, 100, said films being composed of a plurality of layers, 22, 24; 62, 64, 66; 102, 104 respectively, so that each functional layer is placed between at least two dielectric films:
the silver-based layers 40, 80 are deposited using a silver target, under a pressure of 0.8 Pa in a pure argon atmosphere;
the layers 24; 62, 66; 102 are based on ZnO and deposited by reactive sputtering using a zinc target, under a pressure of 0.3 Pa and in an argon/oxygen atmosphere; and
the layers 22, 64 and 104 are based on Si₃N₄ and deposited by reactive sputtering using an aluminum-doped silicon target, under a pressure of 0.8 Pa in an argon/nitrogen atmosphere.

The multilayer coating is covered with a protective layer 200 based on a mixed oxide, such as a mixed tin zinc oxide.

Each functional layer 40, 80 is deposited on an underblocker film 30, 70 consisting, respectively, on the one hand of an interface layer 32, 72, for example made of titanium oxide TiOₓ immediately in contact with said functional layer and, on the other hand, of a metal layer 34, 74 made of a metallic material, for example titanium metal, immediately in contact with said interface layer 32, 72.

FIG. 12 also shows an embodiment, this time with four silver-based functional metallic layers 40, 80, 120, 160 and five dielectric films 20, 60, 100, 140, 180, said films being composed of a plurality of layers, 22, 24; 62, 64, 66; 102, 104, 106; 142, 144, 146; 182, 184, respectively so that each functional layer is placed between at least two dielectric films:
the silver-based layers 40, 80, 120, 160 are deposited using a silver target, under a pressure of 0.8 Pa in a pure argon atmosphere;
the layers 24; 62, 66; 102, 106; 142, 146; 182 are based on ZnO and deposited by reactive sputtering using a zinc target, under a pressure of 0.3 Pa and in an argon/oxygen atmosphere; and
the layers 22, 64, 104, 144 and 184 are based on Si₃N₄ and deposited by reactive sputtering using a boron-doped or aluminum-doped silicon target, under a pressure of 0.8 Pa in an argon/nitrogen atmosphere.

The multilayer coating is also covered with a protective layer 200 based on a mixed oxide, such as a mixed tin zinc oxide.

Each functional layer 40, 80, 120, 160 is deposited on an underblocker film 30, 70, 110, 150 consisting, respectively, on the one hand of an interface layer 32, 72, 112, 152, for example made of titanium oxide TiOₓ immediately in contact with said functional layer, and on the other hand a metal layer 34, 74, 114, 154 made of a metallic material, for example titanium metal, immediately in contact with said interface layer 32, 72, 112, 152 respectively.

The present invention has been described above by way of example. It should be understood that a person skilled in the art is capable of producing various alternative embodiments of the invention without thereby departing from the scope of the patent as defined by the claims.

1. A substrate (10), provided with a thin-film multilayer coating comprising an alternation of n functional layers (40) having reflection properties in the infrared and/or in solar radiation, and (n+1) dielectric films (20, 60), where n≧1, said films being composed of a layer or a plurality of layers (22, 24, 62, 64), including at least one made of a dielectric material, so that each functional layer (40) is placed between at least two dielectric films (20, 60), wherein at least one functional layer (40) includes a blocker film (30, 50) consisting of:
an interface layer (32, 52) immediately in contact with said functional layer, this interface layer being made of a material that is not a metal; or
at least one metal layer (34, 54) made of a metallic material, immediately in contact with said interface layer (32, 52).

2. The substrate (10) as claimed in claim 1, wherein the multilayer coating comprises two functional layers (40, 80) alternating with three films (20, 60, 100).

3. The substrate (10) as claimed in claim 1, wherein the interface layer (32, 52) is based on an oxide and/or on a nitride.

4. The substrate (10) as claimed in claim 1, wherein the metallic layer (34, 54) comprises at least one metal selected from the group consisting of: Ti, V, Mn, Co, Cu, Zn, Zr, Hf, Al, Nb, Ni, Cr, Mo, and Ta; or an alloy based on at least one of said metals.

5. The substrate (10) as claimed claim 4, wherein the metallic layer (34, 54) is based on titanium.

6. The substrate (10) as claimed claim 1, wherein the interface layer (32, 52) is an oxide, a nitride or an oxynitride of at least one metal selected from the group consisting of: Ti, V, Mn, Fe, Co, Cu, Zn, Zr, Hf, Al, Nb, Ni, Cr, Mo, Ta, and W; or an oxide of an alloy based on at least one of said metals.

7. The substrate (10) as claimed in claim 6, wherein the interface layer (32, 52) is an oxide, a nitride or an oxynitride of at least one metal that is present in the metallic layer (34, 54).

8. The substrate (10) as claimed in claim 1, wherein the interface layer (32, 52) is partially oxidized.

9. The substrate (10) as claimed in claim 1, wherein the interface layer (32, 52) is made of TiOₓ where 1.5≦x≦1.99.

10. The substrate (10) as claimed in claim 1, wherein the interface layer (32, 52) has a geometric thickness of less than 5 nm.

11. The substrate (10) as claimed in claim 1, wherein the metallic layer (34, 54) has a geometric thickness of less than 5 nm.

12. The substrate (10) as claimed in claim 1, wherein the blocker film (30, 50) has a geometric thickness of less than 10 nm.

13. A glazing comprising at least one substrate (10) as claimed in claim 1, optionally combined with at least one other substrate.

14. The glazing as claimed in claim 13, mounted as monolithic glazing or as multiple glazing of the double-glazing type or laminated glazing, wherein at least the substrate bearing the multilayer coating is made of curved or toughened glass.

15. A process for manufacturing the substrate (10) as claimed in claim 1, comprising: depositing a thin-film multilayer coating on the substrate (10) by a vacuum technique of sputtering, wherein each layer of a blocker film (30, 50) is deposited by sputtering from a target having a different composition from the target used for depositing at least the adjacent layer.

16. The process as claimed in claim 15, wherein the interface layer (32, 52) is deposited using a ceramic target in a nonoxidizing atmosphere.

17. The process as claimed in claim 15, wherein the targets used for depositing the layers of the blocker film (30, 50) are based on the same chemical element.

18. The process as claimed in claim 17, wherein the same chemical element is Ti.
